(19) United States
(12) Patent Application Publication
(10) Pub. No.: US 2009/0079263 A1
(43) Pub. Date: Mar. 26, 2009

(54) Hybrid energy conversion system with realtime hybrid power display

(75) Inventors: Aaron T. Crumm, Ann Arbor, MI (US); Jonathan R. Rice, Whitmore Lake, MI (US)

Correspondence Address: Adaptive Materials, Inc, 5500 South State Street, Ann Arbor, MI, 48108, US

(73) Assignee: Adaptive Materials, Inc.

(21) Appl. No.: 12/313,534

(22) Filed: Nov. 21, 2008

Related U.S. Application Data
(63) Continuation-in-part of application No. 11/739,742, filed on Apr. 25, 2007.
(60) Provisional application No. 60/795,006, filed on Apr. 26, 2006.

(51) Int. Cl. G01R 19/00; H02J 1/00

(52) U.S. Cl. 307/43; 324/76.11

(57) ABSTRACT

A hybrid energy conversion system includes a first energy conversion device configured to store and generate electrical power and a second energy conversion device configured to generate electrical power. The hybrid energy conversion system further includes a hybrid power sensing device configured to monitor a hybrid power level and a display device signally communicating with the hybrid power sensing device. The display device is configured to display a hybrid power level indicator based on the hybrid power level.

### CROSS-REFERENCE TO RELATED APPLICATIONS

This application is a continuation-in-part of U.S. patent application Ser. No. 11/739,742 filed on Apr. 25, 2007, which claims priority of U.S. Provisional Patent Application No. 60/795,006 filed on Apr. 26, 2006, both of which are hereby incorporated by reference herein.

### FIELD OF THE INVENTION

The invention relates to graphical user interfaces for power generating systems.

### BACKGROUND

The statements in this section merely provide background information related to the present disclosure and may not constitute prior art.

Hybrid energy conversion systems can convert stored energy to useable electrical power by utilizing multiple energy conversion devices. An exemplary hybrid energy conversion system includes a first energy conversion device, for example a rechargeable battery capable of reversibly converting stored energy to electrical power, and a second energy conversion device, for example a fuel cell, capable of generating electrical power. The rechargeable battery can provide power to a power bus of the hybrid energy conversion system by discharging the rechargeable battery and can receive power from the power bus to charge the rechargeable battery. The fuel cell device can continuously convert chemical energy stored in fuel to electrical power to provide electrical power to the power bus.

The power flow between the rechargeable battery and the power bus can be described in terms of a hybrid power level. The hybrid power level can be controlled based on the hybrid energy conversion system's electrical output power to the external devices. When the electrical output power to the external devices is less than a fuel cell power capacity, the fuel cell can provide power to the external devices and to the rechargeable battery and the hybrid power level, as used throughout the present disclosure, is described as negative in that power flows from the power bus to the rechargeable battery. Further, when the electrical output power to the external devices is greater than the fuel cell power capacity, both the fuel cell and the rechargeable battery can provide power to the external devices and, the hybrid power level, as used throughout the present disclosure, is described as positive.

Although the rechargeable battery can be discharged to meet the power requirements of the external devices, typically, much less energy is stored as battery charge than is stored as fuel supplied to the fuel cell. Therefore, while the rechargeable battery can be discharged to power external devices for short periods of time, when the rechargeable battery is discharged rapidly over extended periods of time, the battery state-of-charge will drop to a lower state-of-charge limit.

When the rechargeable battery state-of-charge reaches the lower state-of-charge limit, one of several different strategies can be employed, to prevent further discharge of the rechargeable battery, each of which may result in undesired consequences for the user. For example, the output power supplied to the external devices can be limited to the fuel cell power or the output power supplied to external devices can be discontinued for several minutes to allow the rechargeable battery to charge.

A user can make power management decisions based on power and energy level indicators displayed on a user interface of the hybrid energy conversion system. Exemplary indicators include battery state-of-charge indicators, fuel level indicators, and system operating life indicators. However, none of the exemplary indicators provide the user with real-time hybrid power information and, therefore, users making decisions based on battery state-of-charge or system operating life indicators can make decisions that result in undesirable disruptions or limitations of power to external devices. Therefore, users may utilize a high amount of hybrid power, for example by connecting multiple external devices to the hybrid energy conversion system without considering the real-time effect on power drawn from the rechargeable batteries.

Further, a user making decisions based on fuel level indicators can make decisions that lead to undesirable disruptions of power to external devices. Fuel level is indicative of the long-term energy reserve available to the hybrid energy conversion system. However, when the rechargeable battery is discharged, the power transferred from the hybrid energy conversion system to the external devices can be limited or disrupted regardless of the fuel level of the fuel tank.

A hybrid energy conversion system with a real-time hybrid power display can allow a user to make efficient power management decisions.

### SUMMARY

In accordance with an exemplary embodiment, a hybrid energy conversion system includes a first energy conversion device configured to store and generate electrical power and a second energy conversion device configured to generate electrical power. The hybrid energy conversion system further includes a hybrid power sensing device configured to monitor a hybrid power level and a display device signally communicating with the hybrid power sensing device. The display device is configured to display a hybrid power level indicator based on the hybrid power level.

In accordance with another exemplary embodiment, a method of providing a real-time hybrid power level indicator of a hybrid energy conversion system to a display device includes monitoring a hybrid power level of a hybrid power sensing device. The method further includes providing a signal indicative of the hybrid power level to the display device. The method further includes depicting a hybrid power level indicator based on the hybrid power level of the hybrid power sensing device.

### BRIEF DESCRIPTION OF THE DRAWINGS

FIG. 1 depicts a schematic representation of an hybrid energy conversion system, an electrical connector, and external devices in accordance with an exemplary embodiment of the present disclosure;

FIG. 2 depicts a schematic representation of the hybrid energy conversion system of FIG. 1 and an external device;

FIG. 3 depicts an electric power and signal flow diagram of the hybrid energy conversion system of FIG. 2;

FIG. 4 depicts a circuit diagram of the hybrid energy conversion system of FIG. 2; and

FIG. 5 depicts a graphic user interface of the hybrid energy conversion system of FIG. 2.

### DETAILED DESCRIPTION OF THE EMBODIMENTS

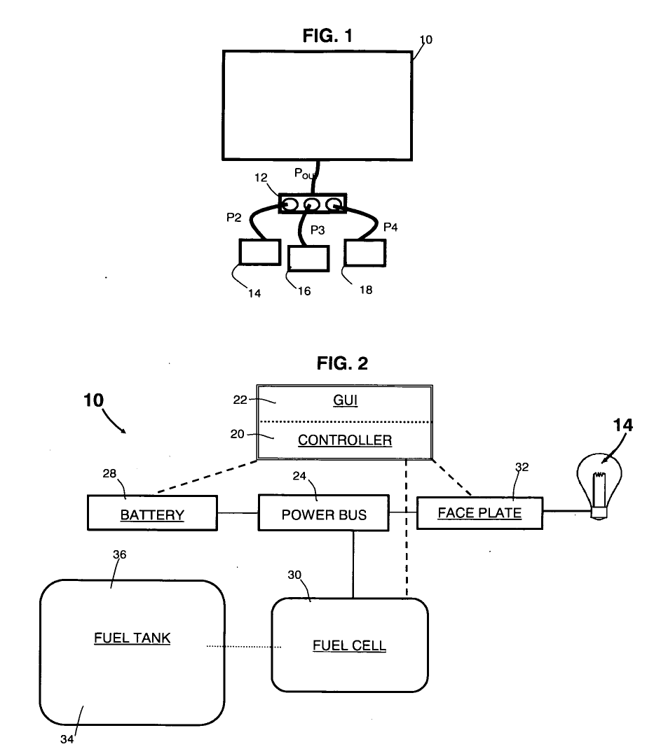

FIG. 1 depicts a hybrid energy conversion system 10, an electrical connector 12, and a plurality of external devices 14, 16, and 18 in accordance with an exemplary embodiment. Although the exemplary embodiment is described with respect to the exemplary hybrid energy conversion system 10 that includes a rechargeable battery 28 and a fuel cell 30, in alternative embodiments, the hybrid energy conversion system can include other types of on-board energy conversion devices. The first energy conversion device can include other types of energy conversion devices that can both store and generate electrical power such as an ultra-capacitor. The second energy conversion device can include other types of devices that can generate electrical power including, for example, a fuel cell, a photovoltaic cell, an electrical generator, a primary battery and like devices.

The hybrid energy conversion system supplies an electrical output power level (‘P_{OUT}’) to the electrical connector 12 and the electrical connector 12 distributes a second electrical power level (‘P2’) to the external device 14, a third electrical power level (‘P3’) to the external device 16, and a fourth electrical power level (‘P4’) to the external device 18. Although the hybrid energy conversion system 10 shown in FIG. 1 is depicted as providing electrical power to three external devices, in alternative embodiments, the hybrid energy conversion system 10 can be configured to provide power to various numbers of external devices in various alternant power flow configurations.

The electrical output power level from the hybrid energy conversion system 10 is controlled to meet the power demands of the plurality external devices 14, 16, 18. For example, when the external device 14 is the only electrical device drawing power from the electrical connector 12, the electrical output power level P_{OUT}, is equal to the second electrical power level P2. When, in addition to the external device 14, the external device 16 draws power from the electrical connector 12, the electrical output power P_{OUT} from the hybrid energy conversion system 10 equals the sum of the second electrical power level P2 and the third electrical power level P3. When, in addition to the external devices 14 and 16, the external device 18 draws power from the electrical connector 12, the electrical output power P_{OUT} from the hybrid power conversion system 10 equals the sum of the second electrical power P2, the third electrical power P3, and the fourth electrical power P4.

As will be discussed in further detail below, the hybrid energy conversion system 10, tracks and displays a hybrid power level in real-time and provides the hybrid power level forthwith to a user of the hybrid energy conversion system 10. Hybrid power as used herein, refers to power being transmitted among two or more energy conversion devices of a hybrid energy conversion system that is generated from or can be stored within a reversible storage device, for example, a rechargeable battery. Therefore, the user can, upon connecting any one of the external devices 14, 16, or 18 and initiating power draw to one of the external devices 14, 16, or 18, immediately recognize the affect that the power draw to the external device has on the hybrid power level of the hybrid energy conversion system, thereby allowing the user to prioritize and affectively manage power transferred to the external devices. In particular, the user can affectively manage power transferred to the external devices based on both the power capacity of the energy storage system and the stored energy available within the hybrid energy conversion system 10.

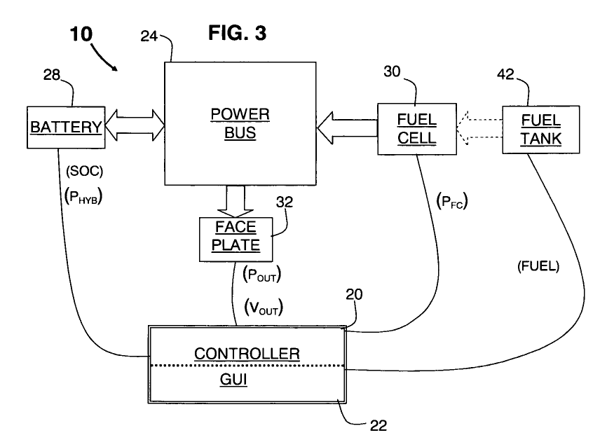

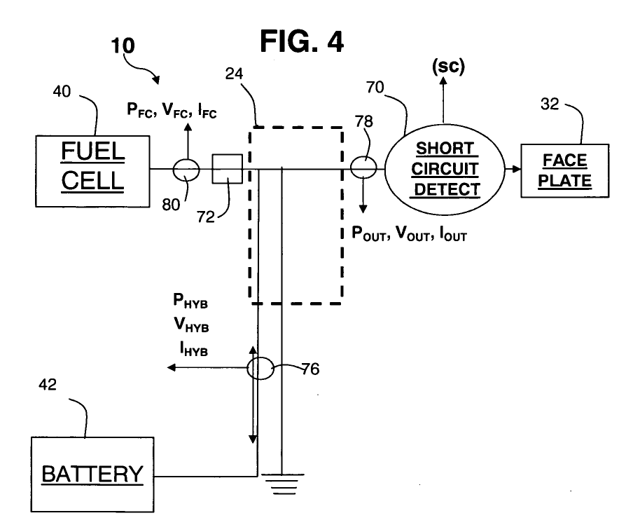

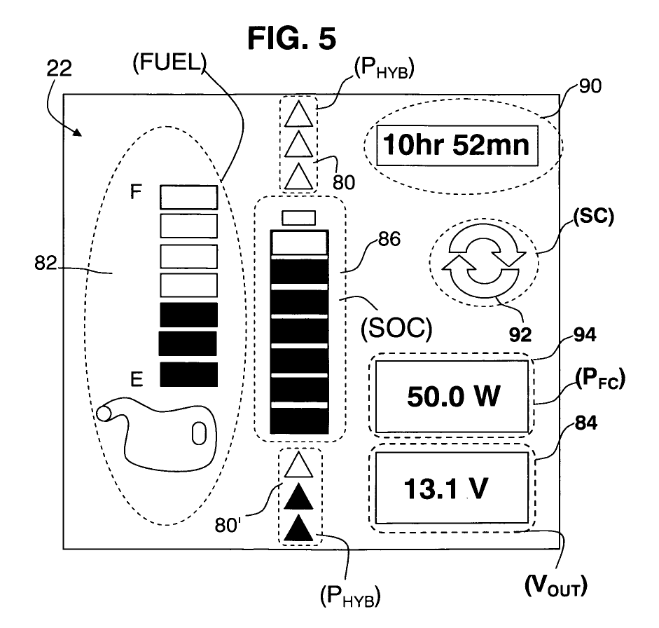

Referring to the schematic diagram of FIG. 2, the electric power and signal flow diagram of FIG. 3, and the circuit diagram of FIG. 4, the hybrid energy conversion system 10 is electrically coupled to an external device 14. The hybrid energy conversion system 10 includes a controller (‘CONTROLLER’) 20, a graphical user interface (hereafter, ‘GUI’) 22, a power bus (‘POWER BUS’) 24, a rechargeable battery (‘BATTERY’) 28, a fuel cell 30, a face plate (‘FACE PLATE) 32, a fuel pump 34 and a fuel tank 36.

The controller 20 comprises a general-purpose digital computer comprising a microprocessor or central processing unit, storage mediums comprising non-volatile memory, a high speed clock, analog-to-digital conversion circuitry, input/output circuitry and devices, and appropriate signal conditioning and buffer circuitry. The controller 20 has a set of control algorithms, comprising resident program instructions and calibrations stored in the non-volatile memory and executed to provide the respective functions. The controller 20 can monitor control signals from sensors disposed throughout the hybrid energy conversion system 10, some of which are described in detail herein below and can execute algorithms in response to the monitored inputs to execute diagnostic routines to monitor power flows and component operations of the hybrid energy conversion system 10.

The power bus 24 comprises an electrically conductive network configured to route power from the energy conversion devices (the rechargeable battery 28 and the fuel cell 30) to the face plate 32. The face plate 32 comprises a plurality of power ports for connecting external devices 14 or electrical connectors 12 to the hybrid energy conversion system 10. In an exemplary embodiment, the power port comprises electrical outlets in which electrical connectors from external devices can be removably connected. In alternative embodiments, the hybrid energy conversion system 10 can include power ports at alternative locations. Further, in alternative embodiments, the hybrid energy conversion system 10 can include power ports that comprise locations at which cables of external devices are hard-wired to the hybrid energy conversion system 10.

The exemplary rechargeable battery 28 is a rechargeable battery configured to receive power from the power bus 24 and to discharge power to the power bus 24. The rechargeable battery 28 can comprise any of several rechargeable battery technologies including, for example, nickel-cadmium, nickel-metal hydride, lithium-ion, and lithium-sulfur technologies. In alternative embodiments, other reversibly storage technologies such as ultra-capacitors can be utilized in addition to or instead of the rechargeable battery 28.

A fuel tank 36 contains a fuel for use by the fuel cell 30. Exemplary fuels include a wide range of hydrocarbon fuels. In an exemplary embodiment, the fuel comprises an alkane fuel and specifically, propane fuel. In alternative embodiments, the fuel can comprise one or more other types of alkane fuel, for example, methane, ethane, propane, butane, pentane, hexane, heptane, octane, and the like, and can include non-linear alkane isomers. Further, other types of hydrocarbon fuel, such as partially and fully saturated hydrocarbons, and oxygenated hydrocarbons, such as alcohols and glycols, can be utilized as fuel that can be converted to electrical energy by the fuel cell 30. The fuel also can include mixtures comprising combinations of various component fuel molecules examples of which include gasoline blends, liquefied natural gas, JP-8 fuel and diesel fuel.

The exemplary fuel cell 30 is a solid oxide fuel cell comprising several component cells, along with various other components, for example, air and fuel delivery manifolds, current collectors, interconnects, and like components, for routing fluid and electrical energy to and from the component cells within the fuel cell 30. In alternative embodiments, other types of fuel cell technology such as proton exchange membrane (PEM), alkaline, direct methanol, and the like can be utilized within the hybrid energy storage device 10 instead of or addition to solid oxide fuel cells. Further, as mentioned above, in alternative embodiments, the hybrid energy conversion system can comprise various other energy conversion devices in addition to or instead of the fuel cell 30.

The hybrid energy conversion system 10 further comprises a short circuit detection circuit 70, a power board 72, a hybrid power sensing circuit 76, an output power sensing circuit 78, and a fuel cell power sensing circuit 80. The short circuit detect circuit 70 is monitored by the controller 20 and the controller 20 disables electrical power to the face plate 32 and resets the hybrid energy conversion system 10 when a short circuit signal (‘SC’) is sent to the controller 20. The power board 72 converts a fuel cell voltage level (‘V_{FC}’) to a primary system voltage that is substantially equal to the hybrid voltage level (‘V_{HYB}’) and the output voltage level (‘V_{OUT}’). Voltage conversion levels between the fuel cell voltage and the primary system voltage can be controlled at the power board 72 and can be adjusted by the controller 20 based on monitored power levels (for example, voltage levels and electrical current levels) at the power sensing circuits 76, 78, and 80.

Each exemplary power sensing circuit 76, 78, 80 comprises a parallel circuit having a resistor disposed in parallel to the primary power flow, along with a voltage and electrical current sensor monitored by the controller 20. Thus, the controller 20 can continuously determine the hybrid power level (‘P_{HYB}’) by continuously monitoring a hybrid current level (‘I_{HYB}’) and a hybrid voltage level (‘V_{HYB}’). Likewise, the controller 20 can continuously determine a fuel cell power level (‘P_{FC}’) by continuously monitoring a fuel cell current level (‘I_{FC}’) and a fuel cell voltage level (‘V_{FC}’) and can continuously determine the electrical output power (‘P_{OUT}’) by continuously monitoring an output current level (‘I_{OUT}’) and an output voltage level (‘V_{OUT}’). Although the hybrid power level, the fuel cell power level, and the output power level are depicted at the exemplary power sensing circuit 76, 78, 80 on FIG. 4, it is to be understood that these values are calculated at the controller 20 based on the respective voltage and current levels. In alternative embodiments, other devices can be utilized, instead of or in addition to the power sensing circuits to measure power within the hybrid energy conversion system 10. Exemplary alternative power sensing devices include both sensors that directly measure power levels and sensors that indirectly measure power levels, for example, sensors utilizing magnetic fields to measure power levels.

The GUI 22 receives signals providing information relating to the operation of the hybrid energy conversion system 10 from the controller 20 and visually displays the information relating to operation of the hybrid energy conversion system 10 to the user. Referring to FIG. 7, the GUI 22 includes hybrid power level indicators 80 and 80′, a fuel level indicator 82, an output voltage indicator 84, a battery state-of-charge indicator 86, an operating life indicator 90, a short-circuit indicator 92, and a fuel cell power indicator 94.

The hybrid power level indicators 80 and 80′ provide illustrative depictions of the hybrid power level (P_{HYB}) monitored by the controller 20. The hybrid power level indicator 80 displays a rate at which power is discharged from the rechargeable battery 28 when the hybrid power is positive by showing triangular-shaped indicia pointing away from a battery icon of the battery state-of-charge indicator 86. The number of filled indicia is indicative of the rate at which the rechargeable battery 28 is being discharged. For example, when the hybrid power level is a large positive power level all three indicia are filled, thereby indicating rapid discharge of the rechargeable battery 28. When the hybrid power level is a small positive power level only one of the three indicia is filled. When the hybrid power level is substantially zero or negative, none of the indicia of the hybrid power level indicator 80 is filled.

The hybrid power level indicator 80′ displays a rate at which power is being charged to the rechargeable battery 28 when the hybrid power level is negative by showing triangular-shaped indicia pointing toward the battery icon of the battery state-of-charge indicator 86 thereby indicating charging of the rechargeable battery 28. The number of filled indicia is indicative of the rate at which the rechargeable battery 28 is being charged. For example, when the hybrid power level is a large negative power level all three indicia are filled, thereby indicating rapid charging of the rechargeable battery 28. When the hybrid power level is a small negative power only one of the three indicia of the hybrid power level indicator 80′ is filled. When the hybrid power level indicator 80′ is substantially zero or positive, none of the indicia of the hybrid power level indicator 80′ is filled. When the hybrid level is substantially zero, the power drawn of the external devices is substantially equal to the power being generated by the fuel cell 30 and therefore, the rechargeable battery 28 neither charges nor discharges. Although, the hybrid power level indicators 80 and 80′ each are shown with three indicia it is to be understood that the hybrid power level indicators can include any number of indicia or can include other means of graphically depicting the hybrid power level such as an icon having a filled-in area indicative of the hybrid power level.

The fuel level indicator 82 depicts the fuel level (‘FUEL’) within the fuel tank 36 measured by a fuel level sensor (not shown) and received by the controller 20. The fuel level indicator depicts a series of bars such that a ratio of filled-in bars to total bars is indicative of the fuel level within the fuel tank 36.

The output voltage indicator 84 displays the output voltage (‘V_{OUT}’) measured at the output power sensing circuit 78. The state-of-charge indicator 86 depicts a battery state-of-charge (‘SOC’) of the battery 42 by showing a series of bars within the battery icon 86. The battery state-of-charge indicator depicts the series of bars such that a ratio of filled-in bars to total bars is indicative of the battery state-of-charge of the rechargeable battery 28. In an exemplary embodiment, the battery state-of-charge is calculated based on the battery voltage (‘V_{BAT}’), the electrical output power (‘P_{OUT}’), and the voltage conversion ratio between the fuel cell voltage and the primary system voltage controlled at power board 72. In an alternative embodiment, the hybrid energy conversion system 10 utilizes a coulomb counter (not shown) to monitor charge entering and exiting the rechargeable battery 28 to determine the battery state-of-charge.

The operating life indicator 90 displays an estimated operating life of the hybrid energy conversion system 10. The operating life can be calculated utilizing one of a variety of methods for predicting operating life based on, for example, based on the fuel level within the fuel tank 36, average fuel consumption levels, short-term and long-term external device load history, power generation, and user defined parameters. The short circuit indicator 92 provides an indication to the user that the short circuit signal (‘SC’) is received by the controller 20 and that system reset has been initiated. The fuel cell power indicator 94 displays the fuel cell power (‘P_{FC}’) measured at the fuel cell power sensing circuit 80.

In alternative embodiments, the GUI 22 can include other indicators depicting further information, for example, output electrical power levels, average fuel consumption levels, temperature levels monitored within the hybrid energy conversion system 10, system error and fault information and like information.

The exemplary embodiments shown in the figures and described above illustrate, but do not limit, the claimed invention. It should be understood that there is no intention to limit the invention to the specific form disclosed; rather, the invention is to cover all modifications, alternative constructions, and equivalents falling within the spirit and scope of the invention as defined in the claims. Therefore, the foregoing description should not be construed to limit the scope of the invention.

1. A hybrid energy conversion system configured to supply electrical output power to an external device, the hybrid energy conversion system comprising:
a first energy conversion device configured to store and generate electrical power;
a second energy conversion device configured to generate electrical power;
a hybrid power sensing device configured to monitor a hybrid power level; and
a display device signally communicating with the hybrid power sensing device, said display device configured to display a hybrid power level indicator based on the hybrid power level.

2. The hybrid energy conversion system of claim 1, wherein the first energy conversion device comprises a rechargeable battery.

3. The hybrid energy conversion system of claim 1, wherein the second energy conversion device comprises a fuel cell.

4. The hybrid energy conversion system of claim 1, wherein the second energy conversion device comprises a solid oxide fuel cell configured to generate power by converting chemical energy from a hydrocarbon fuel into electrical energy.

5. The hybrid energy conversion system of claim 1, wherein the display device is configured to provide real-time updating of the hybrid power level indicator when a level of the electrical output power supplied to the external device changes.

6. The hybrid energy conversion system of claim 1, further comprising a fuel cell power sensing device configured to monitor a fuel cell power level.

7. The hybrid energy conversion system of claim 1, further comprising a power board signally communicating with a controller, said power board being configured to convert electrical power from a fuel cell voltage to a primary system voltage at a voltage conversion factor.

8. The hybrid energy conversion system of claim 7, wherein the voltage conversion factor is adjustable.

9. The hybrid energy conversion system of claim 1, further comprising a fuel tank and a fuel level sensor monitoring a fuel level of the fuel tank, wherein the display device signally communicates with the fuel level sensor and the display device displays a fuel level indicator based on the fuel level.

10. The hybrid energy conversion system of claim 1, wherein the hybrid power level indicator comprises graphical indicia indicative of the hybrid power level of the hybrid energy conversion system.

11. The hybrid energy conversion system of claim 10, wherein the display device further includes a battery state-of-charge indicator, an operating life indicator, and an output voltage indicator.

12. A hybrid energy conversion system configured to supply electrical output power to an external device, said hybrid energy conversion system comprising:
a rechargeable battery;
a fuel cell;
a hybrid power level sensing device;
a power port configured to provide electrical output power from the rechargeable battery and from the fuel cell to a plurality of external devices; and
a display device signally communicating with the hybrid power sensing device, said display device configured to display a hybrid power level indicator based on the hybrid power level of the hybrid power sensing circuit.

13. The method of claim 12, wherein the hybrid energy conversion system is configured to modify the output electrical power based on changes in power demand of the external devices.

14. The hybrid energy conversion system of claim 12, wherein the display device is configured to provide real-time updating of the hybrid power level indicator when the output electrical power supplied to the external devices changes.

15. The hybrid energy conversion system of claim 12, wherein the display device further includes at least one of a battery state-of-charge indicator, a fuel level indicator, an operating life indicator, and an output voltage indicator.

16. A method of providing a real-time hybrid power level indicator of a hybrid energy conversion system to a display device, said method comprising:
monitoring a hybrid power level of a hybrid power sensing device;
providing a signal indicative of the hybrid power level to the display device; and
depicting a hybrid power level indicator based on the hybrid power level of the hybrid power sensing device.

17. The method of claim 16, further comprising graphically depicting the hybrid power level indicator.

18. The method of claim 16, further comprising:
determining a change in hybrid power level; and
modifying the hybrid power level indicator when the change in hybrid power level is determined.

19. The method of claim 18, further comprising determining a change in hybrid power level when a load demand of a first external device electrically coupled to the hybrid energy conversion system increases.

20. The method of claim 19, further comprising detecting a change in hybrid power level when a second external device is electrically coupled to the hybrid energy conversion system.
